(19) United States
(12) Patent Application Publication
(10) Pub. No.: US 2025/0386744 A1
(43) Pub. Date: Dec. 18, 2025

(54) SEMICONDUCTOR DEVICE INCLUDING A PLURALITY OF RESISTANCE CHANGE LAYERS

(71) Applicant: SK hynix Inc., Icheon-si (KR)

(72) Inventors: Won Tae KOO, Icheon-si (KR); Woo Cheol LEE, Icheon-si (KR)

(21) Appl. No.: 18/930,816

(22) Filed: Oct. 29, 2024

(30) Foreign Application Priority Data
Jun. 13, 2024 (KR) 10-2024-0077250

(51) Int. Cl. H10N 70/20; G11C 13/00; H10N 70/00

(52) U.S. Cl. CPC H10N 70/24; G11C 13/0007; G11C 13/0069; H10N 70/841; H10N 70/8833

(57) ABSTRACT

A semiconductor device includes a first electrode layer, a first resistance change layer disposed on the first electrode layer, a first filament control layer disposed on the first resistance change layer, a second resistance change layer disposed on the first filament control layer, a second filament control layer disposed on the second resistance change layer, a third resistance change layer disposed on the second filament control layer, an oxygen vacancy reservoir layer disposed on the third resistance change layer, and a second electrode layer disposed on the oxygen vacancy reservoir layer. A conductive filament corresponding to a resistance state of the semiconductor device is configured to be formed in a direction from the oxygen vacancy reservoir layer to the first electrode layer.

### CROSS-REFERENCE TO RELATED APPLICATION

The present application claims priority under 35 U.S.C. § 119(a) to Korean Application No. 10-2024-0077250, filed in the Korean Intellectual Property Office on Jun. 13, 2024, which is incorporated herein by reference in its entirety.

### BACKGROUND

### 1. Technical Field

The present disclosure generally relates to a semiconductor device including a plurality of resistance change layers.

### 2. Related Art

Generally, a resistance change material refers to a material whose electrical resistance changes when an external stimulus such as heat, current, voltage, or light is applied. The resistance change material can maintain its altered electrical resistance even after the external stimulus is removed. A resistance change memory device is a product that utilizes the electrical characteristics of a resistance change material described above to store signal information.

In a resistance change memory device, the resistance state of the memory layer can switch between a low resistance state and a high resistance state through a set operation and a reset operation.

Depending on the factor causing the switching operation, the resistance change memory device can be classified into a resistive memory (resistive RAM) device, a phase change memory (phase change RAM) device, a magnetic memory (magnetic RAM) device, etc. Among these memory devices, the resistive memory (resistive RAM) can implement different resistance states by generating or blocking an electrical path with low resistance within a resistive change layer when voltage or current is applied to both ends of the resistive change layer.

### SUMMARY

A semiconductor device according to an embodiment of the present disclosure may include a first electrode layer, a first resistance change layer disposed on the first electrode layer, a first filament control layer disposed on the first resistance change layer, a second resistance change layer disposed on the first filament control layer, a second filament control layer disposed on the second resistance change layer, a third resistance change layer disposed on the second filament control layer, an oxygen vacancy reservoir layer disposed on the third resistance change layer, and a second electrode layer disposed on the oxygen vacancy reservoir layer. A conductive filament corresponding to a resistance state of the semiconductor device is configured to be formed in a direction from the oxygen vacancy reservoir layer to the first electrode layer.

A semiconductor device according to another embodiment of the present disclosure may include a first electrode layer, a first resistance change layer disposed on the first electrode layer, a first metal layer disposed on the first resistance change layer has and with a thickness of 0.5 nm to 3 nm, a second resistance change layer disposed on the first metal layer, a second metal layer disposed on the second resistance change layer and that is thinner than the first metal layer, a third resistance change layer disposed on the second metal layer, an oxygen vacancy reservoir layer disposed on the third resistance change layer, and a second electrode layer disposed on the oxygen vacancy reservoir layer.

A semiconductor device according to another embodiment of the present disclosure may include a first electrode layer, a first resistance change layer disposed on the first electrode layer, a first filament control layer disposed on the first resistance change layer, a second resistance change layer disposed on the first filament control layer, a second filament control layer, disposed on the second resistance change layer, that is thinner than the first filament control layer, a third resistance change layer disposed on the second filament control layer, an oxygen vacancy reservoir layer disposed on the third resistance change layer, and a second electrode layer disposed on the oxygen vacancy reservoir layer. A conductive filament corresponding to a resistance state of the semiconductor device is configured to be formed from the oxygen vacancy reservoir layer and the third resistance change layer to reach any one of the first filament control layer, the second filament control layer, and the first electrode layer.

### BRIEF DESCRIPTION OF THE DRAWINGS

FIG. 1 is a schematic cross-sectional view illustrating a semiconductor device according to an embodiment of the present disclosure.

FIG. 2 to FIG. 5 are schematic cross-sectional views illustrating an operation of a semiconductor device according to an embodiment of the present disclosure.

FIG. 6 is a schematic cross-sectional view illustrating an operation of a semiconductor device according to a comparative example.

FIG. 7 is a graph schematically illustrating the conductance distribution of a semiconductor device according to an embodiment of the present disclosure.

FIG. 8 is a graph schematically illustrating the conductance distribution of a semiconductor device according to a comparative example.

FIG. 9 is a graph schematically illustrating a change in conductance value of a semiconductor device depending on a writing voltage.

### DETAILED DESCRIPTION

Hereinafter, embodiments of the present disclosure will be described in detail with reference to the accompanying drawings. In the drawings, in order to clearly express the components of each device, the sizes of the components, such as width and thickness of the components, are enlarged. The terms used herein may correspond to words selected in consideration of their functions in the embodiments, and the meanings of the terms may be construed to be different according to the ordinary skill in the art to which the embodiments belong. If expressly defined in detail, the terms may be construed according to the definitions. Unless otherwise defined, the terms (including technical and scientific terms) used herein have the same meaning as commonly understood by one of ordinary skill in the art to which the embodiments belong.

In addition, expression of a singular form of a word should be understood to include the plural forms of the word unless clearly used otherwise in the context. It will be understood that the terms “comprise”, “include”, or “have” are intended to specify the presence of a feature, a number, a step, an operation, a component, an element, a part, or combinations thereof, but not used to preclude the presence or possibility of addition one or more other features, numbers, steps, operations, components, elements, parts, or combinations thereof.

Terms used in the specification of the present application are terms selected in consideration of functions in the presented embodiments, and the meaning of the terms may vary depending on the intention or customs of a user or operator in the technical field. The meanings of the terms used follow the definitions defined when specifically defined herein, and may be interpreted as meanings generally recognized by those skilled in the art in the absence of specific definitions.

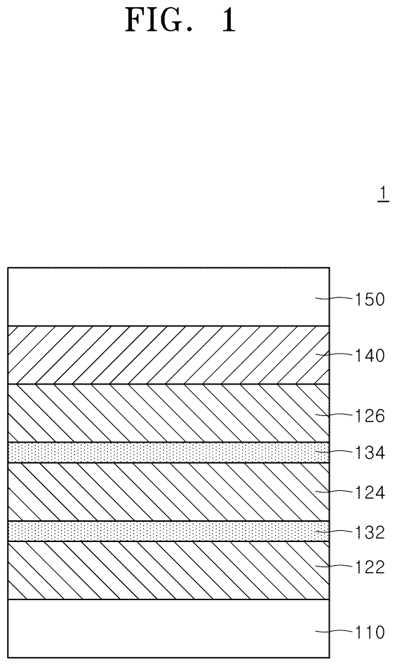

FIG. 1 is a schematic cross-sectional view illustrating a semiconductor device according to an embodiment of the present disclosure.

Referring to FIG. 1, a semiconductor device 1 includes a first electrode layer 110 and a second electrode layer 150 that are disposed to be spaced apart from each other. The semiconductor device 1 includes first, second, and third resistance change layers 122, 124, and 126 that are disposed to be spaced apart from each other between the first electrode layer 110 and the second electrode layer 150. The semiconductor device 1 includes an oxygen vacancy reservoir layer 140, located between the first electrode layer 110 and the second electrode layer 150, that supplies oxygen vacancies to the first, second, and third resistance change layers 122, 124, and 126. The semiconductor device 1 includes a first filament control layer 132 disposed between the first resistance change layer 122 and the second resistance change layer 124, and a second filament control layer 134 disposed between the second resistance change layer 124 and the third resistance change layer 126.

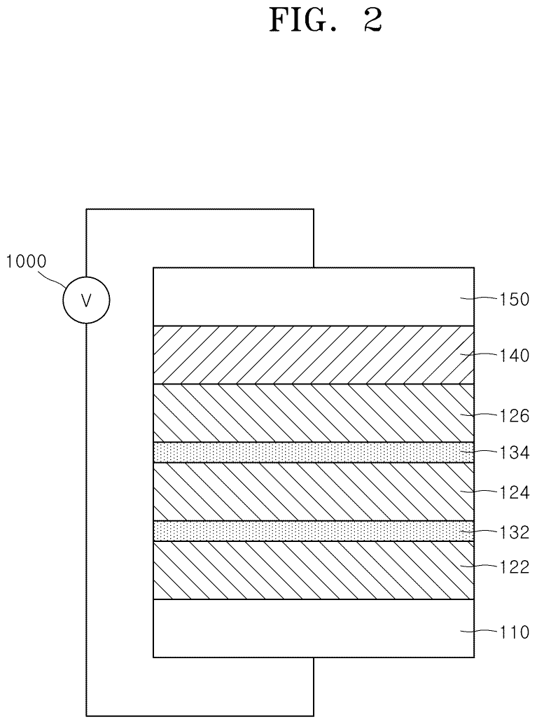

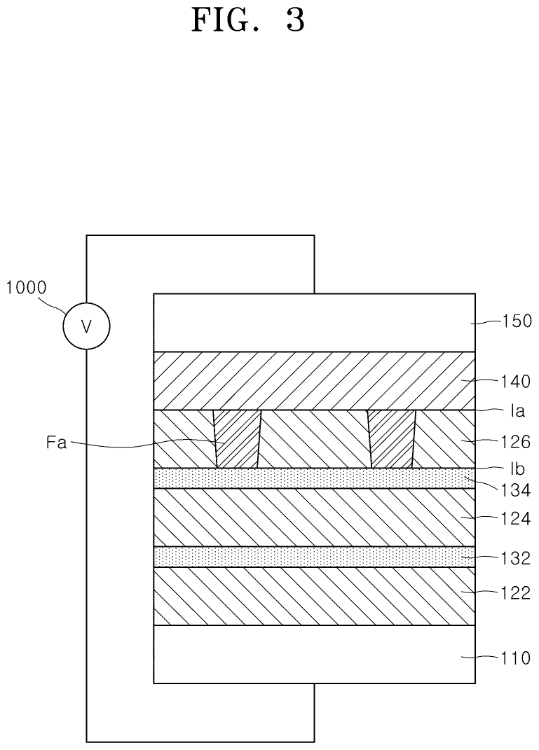

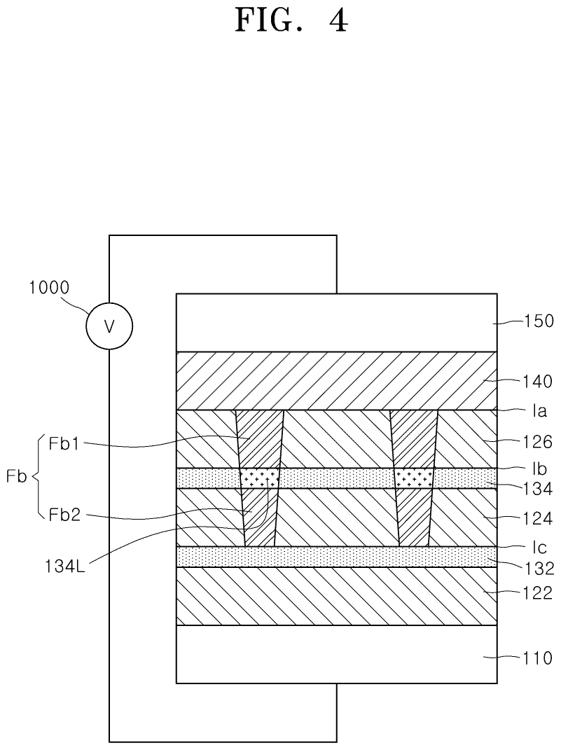

In an embodiment, the semiconductor device 1 may be a resistance change memory device. The semiconductor device 1 is configured such that an electrical resistance state, which is used as signal information, is determined by conductive filaments formed between the first electrode layer 110 and the oxygen vacancy reservoir layer 140. The conductive filaments may be formed within the third resistance change layer 126 as described later with reference to FIG. 2, may be formed within the second and third resistance change layers 124 and 126 as described below with reference to FIG. 3, or may be formed within the first to third resistance change layers 122, 124 and 126 as described below with reference to FIG. 4. The electrical resistance state of the device may depend on the formation, location or distribution of the conductive filaments.

Referring to FIG. 1, the first electrode layer 110 includes a conductive material. The conductive material may include, for example, metal, conductive metal nitride, conductive metal carbide, conductive metal silicide, or conductive metal oxide. The conductive material may include, for example, platinum (Pt), gold (Au), tantalum (Ta), palladium (Pd), molybdenum (Mo), nickel (Ni), tungsten (W), titanium (Ti), copper (Cu), aluminum (Al), ruthenium (Ru), iridium (Ir), iridium oxide, tungsten nitride, titanium nitride, tantalum nitride, tungsten carbide, titanium carbide, tungsten silicide, titanium silicide, tantalum silicide, ruthenium oxide, or a combination of two or more thereof.

In an embodiment, the first electrode layer 110 may include a conductive material having low reactivity with materials in the first resistance change layer 122. As an example, the first electrode layer 110 may include an inert metal such as platinum (Pt), gold (Au), iridium (Ir), or tantalum (Ta).

The first resistance change layer 122 is disposed on the first electrode layer 110. The first resistance change layer 122 may include a resistance change material whose electrical resistance changes when a voltage equal to or higher than a threshold voltage is applied. In addition, the resistance change material may store the changed electrical resistance in a non-volatile manner after the applied voltage is removed.

In an embodiment, the resistance change material may include metal oxide including oxygen vacancies. The metal oxide may not satisfy the stoichiometric ratio. The metal oxide may be in an amorphous state. The resistance change material may include, for example, hafnium oxide, zirconium oxide, hafnium zirconium oxide, or a combination of two or more thereof. As another example, the resistance change material may include titanium oxide, aluminum oxide, nickel oxide, copper oxide, manganese oxide, tungsten oxide, tantalum oxide, niobium oxide, iron oxide, or a combination of two or more thereof.

When an electric field equal to or higher than the threshold voltage is applied to the first resistance change layer 122, oxygen vacancies may aggregate along the electric field direction to form conductive filaments extending in a thickness direction of the first resistance change layer 122. The conductive filaments may provide a path for conductive carriers to move through the first resistance change layer 122.

Referring to FIG. 1, the first filament control layer 132 is disposed on the first resistance change layer 122. The first filament control layer 132 may include metal. The metal may include, for example, platinum (Pt), gold (Au), palladium (Pd), molybdenum (Mo), nickel (Ni), tungsten (W), titanium (Ti), copper (Cu), aluminum (Al), ruthenium (Ru), iridium (Ir), or a combination of two or more thereof. In an embodiment, the first filament control layer 132 may be a layer of single-layer or multi-layer metal. The first filament control layer 132 may have a thickness of, for example, 0.5 nm to 3 nm. The first filament control layer 132 may have a thickness of, as another example, 0.5 nm to 1 nm.

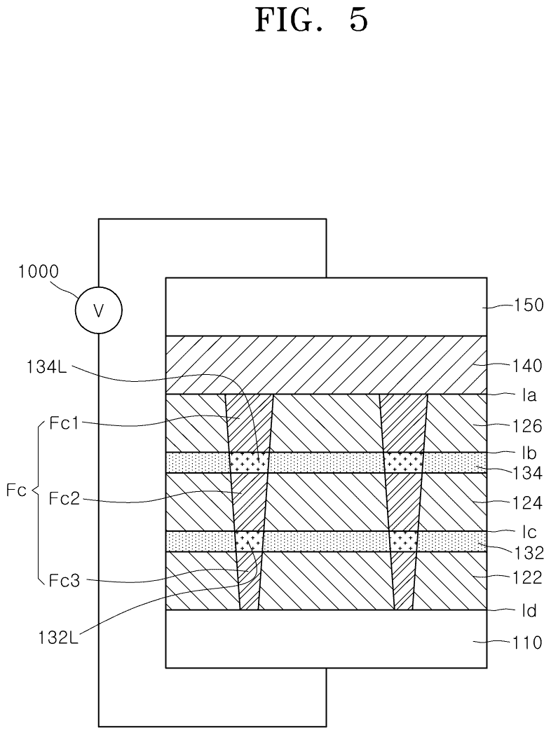

As described below with reference to FIG. 4, when a predetermined second writing voltage is applied, the first filament control layer 132 may serve as a barrier that prevents conductive filaments Fb in FIG. 4, which extend from an interface Ia between the oxygen vacancy reservoir layer 140 and the third resistance change layer 126 to an interface Ic between the second resistance change layer 124 and the first filament control layer 132, from growing into the first resistance change layer 122. Accordingly, when the second writing voltage is applied, the conductive filaments Fb can be controlled to have a uniform length. Meanwhile, as described later with reference to FIG. 5, when a third writing voltage having a sufficient magnitude to overcome the barrier is applied, conductive filaments Fc can grow from the second resistance change layer 124 into the first resistance change layer 122.

Referring to FIG. 1, the second resistance change layer 124 is disposed on the first filament control layer 132. The second resistance change layer 124 may include a resistance change material. The resistance change material may include metal oxide containing oxygen vacancies. The metal oxide may not satisfy the stoichiometric ratio. The metal oxide may be in an amorphous state.

When an electric field equal to or higher than a threshold voltage is applied to the second resistance change layer 124, oxygen vacancies may aggregate along the electric field direction to form conductive filaments extending in the thickness direction of the second resistance change layer 124. The conductive filaments may provide a path for conductive carriers to move through the second resistance change layer 124.

In an embodiment, the resistance change material of the second resistance change layer 124 may be the same as the resistance change material of the first resistance change layer 122. In another embodiment, the resistance change material of the second resistance change layer 124 may be different from the resistance change material of the first resistance change layer 122. In an embodiment, a thickness of the second resistance change layer 124 may be the same as a thickness of the first resistance change layer 122. In another embodiment, the thickness of the second resistance change layer 124 may be different from the thickness of the first resistance change layer 122.

Referring to FIG. 1, the second filament control layer 134 is disposed on the second resistance change layer 124. The second filament control layer 134 may include metal. The metal may include, for example, platinum (Pt), gold (Au), palladium (Pd), molybdenum (Mo), nickel (Ni), tungsten (W), titanium (Ti), copper (Cu), aluminum (Al), ruthenium (Ru), iridium (Ir), or a combination of two or more thereof. In an embodiment, the second filament control layer 134 may be formed of the same material as the first filament control layer 132. In an embodiment, the second filament control layer 134 may be a layer of single-layer or multi-layer metal. As an example, the second filament control layer 134 may be a metal layer having a thickness of 0.5 nm to 3 nm. As another example, the second filament control layer 134 may be a metal layer having a thickness of 0.5 nm to 1 nm. The thickness of the second filament control layer 134 may be thinner than the thickness of the first filament control layer 132.

As described later with reference to FIG. 3, when a predetermined first writing voltage is applied to the semiconductor device 1, the second filament control layer 134 may serve as a barrier that prevents conductive filaments Fa, which extend from the interface Ia between the oxygen vacancy reservoir layer 140 and the third resistance change layer 126 to the interface Ib between the third resistance change layer 126 and the second filament control layer 134, from growing into the second resistance change layer 124.

Accordingly, when the first writing voltage is applied, the conductive filaments Fa may be controlled to have a uniform length. Meanwhile, as described later with reference to FIG. 4, when the second writing voltage is applied with a magnitude sufficient to overcome the barrier, the conductive filaments Fa can grow into the second resistance change layer 124.

Referring to FIG. 1, the third resistance change layer 126 is disposed on the second filament control layer 134. The third resistance change layer 126 may include a resistance change material. The resistance change material may include metal oxide containing oxygen vacancies. The metal oxide may not satisfy the stoichiometric ratio. The metal oxide may be in an amorphous state.

When an electric field equal to higher than a threshold voltage is applied to the third resistance change layer 126, oxygen vacancies may aggregate along the direction of the electric field to form conductive filaments extending in the thickness direction of the third resistance change layer 126. The conductive filaments can provide a path for conductive carriers to move through the third resistance change layer 126.

In an embodiment, the resistance change material of the third resistance change layer 126 may be the same material as the resistance change material of the at least one of the first resistance change layer 122 and second resistance change layer 124. In an embodiment, a thickness of the third resistance change layer 126 may be substantially the same as a thickness of at least one of the first resistance change layer 122 and second resistance change layer 124. In another embodiment, the thickness of the third resistance change layer 126 may be different from the thickness of each of the first resistance change layer 122 and second resistance change layer 124.

Referring to FIG. 1, the oxygen vacancy reservoir layer 140 is disposed on the third resistance change layer 126. When a set voltage is applied between the first electrode layer 110 and the second electrode layer 150, the oxygen vacancy reservoir layer 140 may provide oxygen vacancies to the third resistance change layer 126. The oxygen vacancies provided to the third resistance change layer 126 may diffuse to the first resistance change layer 122 and the second resistance change layer 124. In the diffusion process, the oxygen vacancies may pass through the first filament control layer 132 and the second filament control layer 134. In addition, the oxygen vacancy reservoir layer 140 receives the oxygen vacancies from the third resistance change layer 126 when a reset voltage is applied between the first electrode layer 110 and the second electrode layer 150. The oxygen vacancies may move from the first resistance change layer 122 via the second resistance change layer 124 to the third resistance change layer 126 along the electric field formed by the reset voltage.

In an embodiment, the oxygen vacancy reservoir layer 140 may include metal having excellent reactivity with oxygen. The metal may include, for example, tantalum (Ta), titanium (Ti), zirconium (Zr), vanadium (V), tungsten (W), ruthenium (Ru), or a combination of two or more thereof. In another embodiment, the oxygen vacancy reservoir layer 140 may include metal oxide that does not satisfy a stoichiometric ratio. The metal oxide may be deficient in the oxygen content that establishes the stoichiometric ratio. The metal oxide may be, for example, tantalum oxide, titanium oxide, zirconium oxide, tungsten oxide, aluminum oxide, nickel oxide, copper oxide, manganese oxide, hafnium oxide, niobium oxide, iron oxide, or a combination of two or more thereof.

Referring to FIG. 1, the second electrode layer 150 is disposed on the oxygen vacancy reservoir layer 140. The second electrode layer 150 may include a conductive material. The conductive material may include, for example, metal, conductive metal nitride, conductive metal carbide, conductive metal silicide, or conductive metal oxide. A configuration of the second electrode layer 150 may be substantially the same as a configuration of the first electrode layer 110.

As described above, according to an embodiment of the present disclosure, a semiconductor device 1 includes the first to third resistance change layers 122, 124 and 126 disposed between the first electrode layer 110 and the second electrode layer 150. In addition, the semiconductor device 1 includes the first filament control layer 132 disposed between the first resistance change layer 122 and the second resistance change layer 124, and the second filament control layer 134 disposed between the second resistance change layer 124 and the third resistance change layer 126. The first and second filament control layers 132 and 134 control the growth of the filaments formed inside the first to third resistance change layers 122, 124 and 126 during the operation of the semiconductor device 1, thereby improving the distribution characteristics of filaments that implement multi-level signals.

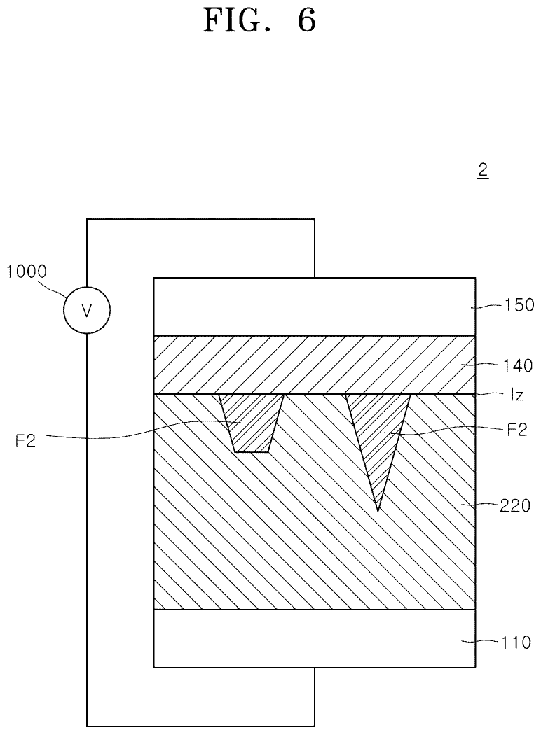

FIG. 2 to FIG. 5 are schematic cross-sectional views illustrating an operation of a semiconductor device according to an embodiment of the present disclosure. The operation of the semiconductor device shown in FIG. 2 to FIG. 5 can be explained by reference to a semiconductor device 1 of FIG. 1. FIG. 6 is a schematic cross-sectional view illustrating an operation of a semiconductor device according to a comparative example. Compared to FIG. 1 illustrating a semiconductor device 1, as an embodiment of the present disclosure, a semiconductor device 2 according to a comparative example does not include the first and second filament control layers 132 and 134.

Referring to FIG. 2 to FIG. 5, the semiconductor device 1 includes the first to third resistance change layers 122, 124 and 126 that are electrically connected to each other in series between the first electrode layer 110 and the second electrode layer 150. Each of the first, second, and third resistance change layers 122, 124, and 126 may have a one of a high resistance state and a low resistance state depending on whether filaments are formed in each respective layer.

A voltage source 1000 is provided to apply a voltage between the first electrode layer 110 and the second electrode layer 150. The voltage source 1000 provides a voltage that changes the resistance state of the first to third resistance change layers 122, 124 and 126. The semiconductor device 1 may have multiple levels of signal information determined by changes in the resistance states of the first to third resistance change layers 122, 124 and 126.

Referring to FIG. 2, in an initial state of the semiconductor device 1, all of the first to third resistance change layers 122, 124 and 126 are initially in a high resistance state. In the initial state, conductive filaments are not formed inside the first to third resistance change layers 122, 124 and 126. Semiconductor device 1 stores, as first signal information, the high resistance state of the first to third resistance change layers 122, 124 and 126.

Referring to FIG. 3, a first writing voltage is applied between the first electrode layer 110 and the second electrode layer 150 by the voltage source 1000. Through the application of the first writing voltage, second signal information is written in the semiconductor device 1. The first writing voltage is referred to as a “first set voltage”.

In an embodiment, the first writing voltage may be applied by applying a bias of a positive polarity to the second electrode layer 150 and applying a ground bias to the first electrode layer 110. The oxygen vacancy reservoir layer 140 may provide oxygen vacancies to the third resistance change layer 126 under the electric field formed by the first writing voltage. In addition, along the electric field, the oxygen vacancies in the third resistance change layer 126 may be aggregated to form the first conductive filaments Fa.

The first conductive filaments Fa may extend from the interface Ia between the oxygen vacancy reservoir layer 140 and the third resistance change layer 126 to the interface Ib between the third resistance change layer 126 and the second filament control layer 134. The second filament control layer 134 can prevent the first conductive filaments Fa from growing from the third resistance change layer 126 to the second resistance change layer 124 when the first writing voltage is applied. The second filament control layer 134 may maintain an electrically floated state. Due to the second filament control layer 134, the first conductive filaments Fa can be controlled to be distributed only within the third resistance change layer 126.

Even after the first writing voltage is removed, the first conductive filaments Fa may remain in the third resistance change layer 126. The electrical resistance of the third resistance change layer 126 is reduced by the first conductive filament Fa. Accordingly, the first resistance change layer 122 and the second resistance change layer 124 can maintain a high resistance state, and the third resistance change layer 126 can maintain a low resistance state. As a result, the electrical resistance between the first electrode layer 110 and the second electrode layer 150 illustrated in FIG. 3 can be decreased, compared to the electrical resistance between the first electrode layer 110 and the second electrode layer 150 illustrated in FIG. 2. The semiconductor device 1 can store, as second signal information that is different from the first signal information described with reference to FIG. 2, the decrease in the electrical resistance.

Referring to FIG. 4, a second writing voltage is applied between the first electrode layer 110 and the second electrode layer 150 by the voltage source 1000. By applying the second writing voltage, third signal information can be written in the semiconductor device 1. The second writing voltage may be referred to as a “second set voltage”.

In an embodiment, the second writing voltage may be applied by applying a bias of a positive polarity to the second electrode layer 150 and applying a ground bias to the first electrode layer 110. The magnitude of the second writing voltage may be greater than the magnitude of the first writing voltage described with reference to FIG. 3. In an embodiment, the second writing voltage may be applied by applying a voltage having a greater amplitude than the first writing voltage. In another embodiment, when the first writing voltage is a pulse voltage, the second writing voltage may be applied by applying the pulse voltage with a pulse application time longer than the pulse application time of the first writing voltage.

Under the electric field formed by the second writing voltage, the oxygen vacancy reservoir layer 140 may provide oxygen vacancies to the third resistance change layer 126. The oxygen vacancies may diffuse through the second filament control layer 134 to the second resistance change layer 124.

Along the electric field, the oxygen vacancies within the second resistance change layer 124 and third resistance change layer 126 may aggregate to form the second conductive filaments Fb. The second conductive filaments Fb may extend from the interface Ia, between the oxygen vacancy reservoir layer 140 and the third resistance change layer 126, to reach the interface Ic between the second resistance change layer 124 and the first filament control layer 132.

In an embodiment, the second conductive filaments Fb may extend into the second resistance change layer 124, as compared to the first conductive filaments Fa of FIG. 3. In an embodiment, the second conductive filament Fb includes a first filament part Fb1 disposed in the third resistance change layer 126 and a second filament part Fb2 disposed in the second resistance change layer 124. The first filament part Fb1 may be disposed to overlap the second filament part Fb2 in a vertical direction (i.e., the direction of the electric field) with the second filament control layer 134 interposed therebetween.

Referring to FIG. 4, when the second writing voltage is applied, the electric field may be concentrated on an internal region 134L in the second filament control layer 134 located directly below the first filament part Fb1 in the third resistance change layer 126. The internal region 134L may be formed through the second filament control layer 134, which has a thickness of 0.5 nm to 3 nm. That is, an electric field localization phenomenon may occur in the internal region 134L of the second filament control layer 134. In addition, the electric field may be formed to extend from the first filament part Fb1 through the internal region 134L, where the electric field localization phenomenon occurs, into the interior of the second resistance change layer 124. The second filament part Fb2 may be formed in the second resistance change layer 124 located directly below the first filament part Fb1 along the electric field.

Even after the second writing voltage is removed, the second conductive filaments Fb including the first and second filament parts Fb1 and Fb2 may remain within the second resistance change layer 124 and the third resistance change layer 126. The second conductive filaments Fb extend from the third resistance change layer 126 to the second resistance change layer 124, so the resistance state of the second resistance change layer 124 may be further altered from a higher resistance state towards a lower resistance state. Accordingly, while the first resistance change layer 122 has a high resistance state, the second resistance change layer 124 and third resistance change layer 126 can have a low resistance state. As a result, the electrical resistance between the first electrode layer 110 and the second electrode layer 150 illustrated in FIG. 4 is less than the electrical resistance between the first electrode layer 110 and the second electrode layer 150 illustrated in FIG. 3. The semiconductor device 1 can store the third signal information as a distinct signal information, based on the decrease in the electrical resistance, that is different from the second signal information described with reference to FIG. 3.

Referring to FIG. 5, a third writing voltage is applied between the first electrode layer 110 and the second electrode layer 150 by the voltage source 1000. By applying the third writing voltage, fourth signal information may be written in the semiconductor device 1. The third writing voltage may be referred to as a “third set voltage”.

In an embodiment, the third writing voltage may be applied by applying a bias of a positive polarity to the second electrode layer 150 and applying a ground bias to the first electrode layer 110. The magnitude of the third writing voltage may be greater than the magnitude of the second writing voltage described with reference to FIG. 4. In an embodiment, the third writing voltage may be applied by applying a voltage having a greater amplitude than the second writing voltage. In another embodiment, when the second writing voltage is a pulse voltage, the third writing voltage may be applied by applying the pulse voltage with a pulse application time longer than the pulse application time of the second writing voltage.

The oxygen vacancy reservoir layer 140 may provide oxygen vacancies to the third resistance change layer 126 under the electric field formed by the third writing voltage. The oxygen vacancies may diffuse through the second filament control layer 134 to the second resistance change layer 124. The oxygen vacancies may diffuse through the first filament control layer 132 to the first resistance change layer 122.

Along the electric field, oxygen vacancies within the first to third resistance change layers 122, 124 and 126 may aggregate to form third conductive filaments Fc. The third conductive filaments Fc may extend from the interface Ia, between the oxygen vacancy reservoir layer 140 and the third resistance change layer 126, to reach an interface Id between the first resistance change layer 122 and the first electrode layer 110. Accordingly, the third conductive filaments Fc may electrically connect the first electrode layer 110 to the second electrode layer 150.

In an embodiment, the third conductive filaments Fc may be additionally formed inside the first resistance change layer 122, compared to the second conductive filaments Fb of FIG. 4. In an embodiment, the third conductive filament Fc includes a first filament part Fc1 disposed in the third resistance change layer 126, a second filament part Fc2 disposed in the second resistance change layer 124, and a third filament part Fc3 disposed in the first resistance change layer 122. The first filament parts Fc1 are disposed to overlap the second filament parts Fc2 vertically with the second filament control layer 134 therebetween. The second filament parts Fc2 are disposed to overlap the third filament parts Fc3 vertically with the first filament control layer 132 therebetween.

Referring to FIG. 5, when the third writing voltage is applied, the electric field may be concentrated on the internal region 132L of the first filament control layer 132 located directly below the second filament part Fc2 of the second resistance change layer 124. The internal region 132L may be formed through the first filament control layer 132, which has a thickness of 0.5 nm to 3 nm. That is, an electric field localization phenomenon may occur in the internal region 132L of the first filament control layer 132. In addition, the electric field may be formed to extend from the second filament part Fc2 through the internal region 132L where the electric field localization phenomenon occurs into the interior of the first resistance change layer 122. The third filament part Fc3 may be formed in the first resistance change layer 122 located directly below the second filament part Fc2 along the electric field.

Even after the third writing voltage is removed, the third conductive filaments Fc including the first to third filament parts Fc1, Fc2 and Fc3 may remain within the first to third resistance change layers 122, 124 and 126. The third conductive filaments Fc extend from the second resistance change layer 124 to the first resistance change layer 122, so the resistance state of the first resistance change layer 122 may be lowered from a higher resistance state to a lower resistance state. Accordingly, the first to third resistance change layers 122, 124 and 126 may each have a low resistance state. As a result, the electrical resistance between the first electrode layer 110 and the second electrode layer 150 illustrated in FIG. 5 can be lower than the electrical resistance between the first electrode layer 110 and the second electrode layer 150 as described above and illustrated in FIG. 4. With the additional decrease in the electrical resistance, the semiconductor device 1 can store the fourth signal information as distinct signal information that is different from the third signal information described with reference to FIG. 4.

As described above, in the semiconductor device 1, conductive filaments may be absent from the first to third resistance change layers 122, 124 and 126 or may be disposed in one or more identifiable layers within the first to third resistance change layers 122, 124 and 126. That is, the conductive filaments extend from the interface Ia between the oxygen vacancy reservoir layer 140 and the third resistance change layer 126, and may reach any one of the interface Ib between the second filament control layer 134 and the third resistance change layer 126, the interface Ic between the first filament control layer 132 and the second resistance change layer 124, and the interface Id between the first electrode layer 110 and the first resistance change layer 122. The electrical resistance state of the semiconductor device 1, which depends on the arrangement form of the conductive filaments, can be determined.

In some embodiments, the thickness of the second filament control layer 134 may be thinner than the thickness of the first filament control layer 132. As the thickness of the filament control layer becomes thinner, the effect of electric field localization occurring inside the filament control layer is strengthened, and the concentration of oxygen vacancies passing through the filament control layer can be increased. By controlling the thickness of the second filament control layer 134 to be thinner than the thickness of the first filament control layer 132, it is possible to provide oxygen vacancies that sequentially diffuse from the third resistance change layer 126 to the first resistance change layer 122 through the second resistance change layer 124 under a predetermined writing voltage. With enough oxygen vacancies diffusing to the first resistance change layer 122, conductive filaments extending from the third resistance change layer 126 to the first resistance change layer 122 can be effectively generated.

Embodiments of the disclosure include reset operations, in which the signal storage state of the semiconductor device 1 can be converted to an initial state. For example, from a state where second signal information generated by first conductive filaments Fa of FIG. 3 is stored, from a state where third signal information generated by second conductive filaments Fb of FIG. 4 is stored, or from a state where the fourth signal information generated by third conductive filaments Fc of FIG. 5 is stored, a semiconductor device 1 can return to a state with first signal information as illustrated in FIG. 2 by performing a reset operation.

A reset operation may be performed by applying a reset voltage between the first electrode layer 110 and the second electrode layer 150. The reset voltage may be applied by applying a bias of a negative polarity to the second electrode layer 150 and applying a ground bias to the first electrode layer 110 using the voltage source 1000. Through the reset operation, the oxygen vacancies constituting the first, second, and third conductive filaments Fa, Fb, and Fc are decomposed and released into the first to third resistance change layers 122, 124 and 126. As a result, the first to third conductive filaments Fa, Fb, and Fc degrade in the first to third resistance change layers 122, 124, and 126 and can be electrically disconnected. After the reset voltage is removed, the first, second, and third resistance change layers 122, 124, and 126 can each maintain a high resistance state.

In some embodiments, when the semiconductor device 1 stores the fourth signal information of FIG. 5, the state of the semiconductor device 1 may be converted into a state for storing the second signal information of FIG. 3 or a state for storing the third signal information of FIG. 4 by applying a reset voltage of a predetermined magnitude. As an example, the absolute magnitude of the reset voltage applied to convert the state of the semiconductor device 1 having fourth signal information into a state for storing second signal information may be greater than the absolute magnitude of the reset voltage applied to convert the state of the semiconductor device 1 having fourth signal information into a state for storing third signal information. In another embodiment, when the semiconductor device 1 stores the third signal information of FIG. 4, the state of the semiconductor device 1 may be converted into a state for storing the second signal information in FIG. 3 or a state for storing the third signal information in FIG. 4 by applying the reset voltage of a predetermined magnitude.

As described above, according to embodiments of the present disclosure, semiconductor devices include first to third resistance change layers (e.g., 122, 124 and 126) and the first and second filament control layers (e.g., 132 and 134). However, the present disclosure is not necessarily limited thereto. In other embodiments, semiconductor devices may include four or more resistance change layers spaced apart from each other between the first electrode layer and the oxygen vacancy reservoir layer. Additionally, semiconductor devices may include three or more filament control layers disposed between the four or more resistance change layers. With three or more filament control layers, a thickness of an uppermost filament control layer adjacent to the oxygen vacancy reservoir layer may be the thinnest, and a thickness of a lowest filament control layer adjacent to the first electrode layer may be the thickest, so that the oxygen vacancies are more effectively transferred from the oxygen vacancy reservoir layer to the lowest resistance change layer. In some embodiments, with three or more filament control layers, the uppermost filament control layer adjacent to the oxygen vacancy reservoir layer may be thickest, and the lowest filament control layer adjacent to the first electrode layer may be the thinnest. In this case, oxygen vacancies can be more effectively transferred from the lowest resistance change layer to the uppermost resistance change layer.

FIG. 6 is a diagram illustrating an operation of a semiconductor device according to a comparative example. Referring to FIG. 6, a semiconductor device 2 includes a first electrode layer 110, a resistance change layer 220, an oxygen vacancy reservoir layer 140, and a second electrode layer 150. When compared to a semiconductor device 1, semiconductor device 2 does not include first and second filament control layers 132 and 134. The material properties of the resistance change layer 220 are substantially the same as those of first to third resistance change layers 122, 124, and 126. The thickness of the resistance change layer 220 may be equal to the sum of the thicknesses of the first to third resistance change layers 122, 124 and 126.

Referring to FIG. 6, because the filament control layer is excluded, when a predetermined writing voltage is applied, the lengths of conductive filaments F2 formed in the resistance change layer 220 may not be uniform. According to the comparative example, when the semiconductor device 2 stores multi-level signal information, a plurality of resistance states may be determined depending on the lengths of the conductive filaments F2 formed inside the resistance change layer 220 from an interface Iz between the oxygen vacancy reservoir layer 140 and the resistance change layer 220. Compared to the semiconductor device 1 of embodiments of the present disclosure, the semiconductor device 2 without a filament control layer may have a relatively poor ability to control the lengths of the conductive filaments F2. As a result, the semiconductor device 2 may be inferior to the semiconductor device 1 in terms of reproducibly implementing distinctly measurable resistance states under predetermined applied voltages. Also, the semiconductor device 2 is less reliable in implementing a plurality of different resistance states.

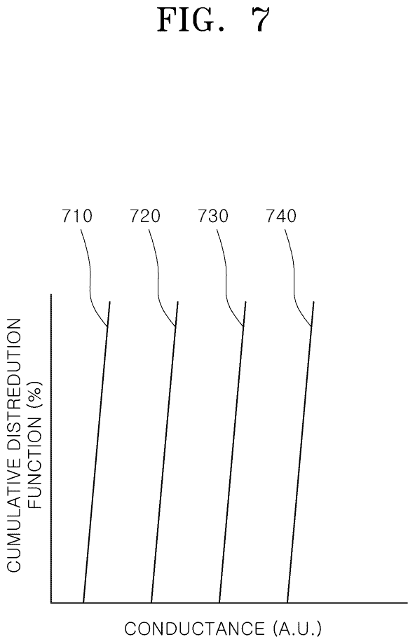

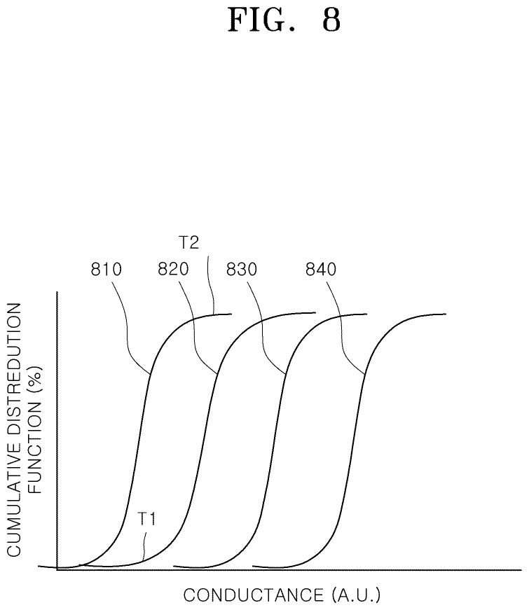

FIG. 7 is a graph schematically illustrating the conductance distribution of a semiconductor device according to an embodiment of the present disclosure. FIG. 8 is a graph schematically illustrating the conductance distribution of a semiconductor device according to a comparative example. In FIG. 7, a semiconductor device of the embodiment may be a semiconductor device 1 described above with reference to FIG. 1 to FIG. 5, and in FIG. 8 a semiconductor device of the comparative example may be a semiconductor device 2 described above with reference to FIG. 6.

Referring to FIG. 7, semiconductor device 1 may exhibit different first, second, third, and fourth conductance values 710, 720, 730, and 740. That is, the semiconductor device 1 may have resistance states corresponding to the first to fourth conductance values 710, 720, 730, and 740, respectively, as signal information. Referring to FIG. 8, semiconductor device 2 according to the comparative example may have different first to fourth conductance values 810, 820, 830, and 840. That is, the semiconductor device 2 may have resistance states corresponding to the first to fourth conductance values 810, 820, 830, and 840, respectively, as signal information.

Each of the first to fourth conductance values 710, 720, 730, and 740 of the semiconductor device 1 with a filament control layer can be implemented to have a uniform distribution with small conductance deviation, compared to the first to fourth conductance values 810, 820, 830, and 840 of the semiconductor device 2 without a filament control layer.

Specifically, referring to FIG. 8, a phenomenon may occur in which an upper tail T2 of the first conductance value 810 overlaps with a lower tail T1 of the second conductance value 820 due to a relatively large conductance deviation. In this case, an error may occur in identification of signal information between the first conductance value 810 and the second conductance value 820. Likewise, a phenomenon may occur in which the upper tail of the second conductance value 820 overlaps the lower tail of the third conductance value 830, and the upper tail of the third conductance value 830 overlaps the lower tail of the fourth conductance value 840. On the other hand, referring to FIG. 7, in embodiments of the present disclosure, because the first to fourth conductance values 710, 720, 730, and 740 have distinct conductance distributions that do not overlap, different adjacent signal information can be effectively identified.

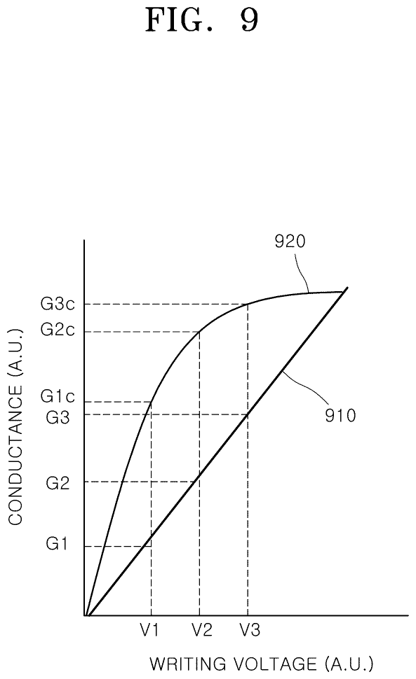

FIG. 9 is a graph schematically illustrating a change in conductance value of a semiconductor device depending on a writing voltage. First graph 910 of FIG. 9 shows the change in the conductance value of a semiconductor device according to embodiments of the disclosure. The first graph 910 may represent a change in conductance value derived from a semiconductor device 1 described with reference to FIG. 1 to FIG. 5. Second graph 920 of FIG. 9 shows a change in the conductance value of a semiconductor device according to a comparative example.

Referring to the first graph 910 of FIG. 9, the semiconductor device 1 may exhibit a first conductance value G1 when a first writing voltage V1 is applied. The first conductance value G1 may correspond to the second signal information described above with reference to FIG. 3. Additionally, the semiconductor device 1 may exhibit second and third conductance values G2 and G3 at the second and third writing voltages V2 and V3, respectively. The second and third conductance values G2 and G3 may correspond to the third and fourth signal information described above with reference to FIG. 4 and FIG. 5, respectively.

The first graph 910 of FIG. 9 may be substantially a straight line with a positive slope. The first to third conductance values G1, G2, and G3 may be located linearly on the first graph 910. That is, as the magnitude of the writing voltage applied to the semiconductor device 1 increases, the magnitude of signal information stored in the semiconductor device 1 may substantially linearly increase.

Accordingly, the semiconductor device 1 can store multi-level signal information whose magnitude changes linearly. A semiconductor device 1 can be applied to the cell structure of an analog computation in memory (ACiM) and can be implemented using a plurality pieces of signal information with linearly increasing or decreasing conductance magnitudes.

Referring to the second graph 920 of FIG. 9, when first to third writing voltages V1, V2, and V3 are applied to the semiconductor device 2, the semiconductor device 2 may exhibit first to third conductance values G1c, G2c, and G3c. The first to third conductance values G1c, G2c, and G3c may be non-linear as seen in second graph 920. The semiconductor device 2 of the comparative example, which does not include first and second filament control layers 132 and 134, may have higher conductance values at the same writing voltage, compared to the semiconductor device 1 of embodiments of the disclosure. However, as the magnitude of the writing voltage increases, the increase in conductance value may decrease in semiconductor device 2.

As described above, in embodiments of the present disclosure, semiconductor devices may include filament control layers disposed between a plurality of resistance change layers. The filament control layers can control filament growth from one resistance change layer to another resistance change layer. The filament whose size is controlled by the filament control layer reduces the resistance variation of the resistance change layers, so that the semiconductor device can implement multi-level signal information more reliably. In addition, multi-level signal information can be implemented to have characteristics of linearly changing conductance, so that the semiconductor devices can be effectively applied to the cell structure of an analog arithmetic device.

Concepts are disclosed in conjunction with various embodiments as described above. Those skilled in the art will understand that various modifications, additions, and substitutions are possible, without departing from the scope and spirit of the present disclosure. Accordingly, the embodiments disclosed in the present specification shou Id not be considered from a restrictive standpoint but rather from an illustrative standpoint. The scope of the present disclosure is not limited to the above descriptions, and all of distinctive features within an equivalent scope should be construed as being included in the present disclosure.

What is claimed is:

1. A semiconductor device comprising:
a first electrode layer;
a first resistance change layer disposed on the first electrode layer;
a first filament control layer disposed on the first resistance change layer;
a second resistance change layer disposed on the first filament control layer;
a second filament control layer disposed on the second resistance change layer;
a third resistance change layer disposed on the second filament control layer;
an oxygen vacancy reservoir layer disposed on the third resistance change layer; and
a second electrode layer disposed on the oxygen vacancy reservoir layer,
wherein a conductive filament corresponding to a resistance state of the semiconductor device is configured to be formed in a direction from the oxygen vacancy reservoir layer to the first electrode layer.

2. The semiconductor device of claim 1, wherein a thickness of the second filament control layer is thinner than a thickness of the first filament control layer.

3. The semiconductor device of claim 1,
wherein each of the first filament control layer and the second filament control layer includes metal, and
wherein the metal includes at least one selected from the group consisting of platinum (Pt), gold (Au), palladium (Pd), molybdenum (Mo), nickel (Ni), tungsten (W), titanium (Ti), copper (Cu), aluminum (Al), ruthenium (Ru), and iridium (Ir).

4. The semiconductor device of claim 1, wherein the first filament control layer has a thickness of 0.5 nm to 3 nm, and the second filament control layer is thinner than the first filament control layer.

5. The semiconductor device of claim 1,
wherein each of the first to third resistance change layers includes a resistance change material, and
wherein the resistance change material includes at least one of hafnium oxide, zirconium oxide, and hafnium zirconium oxide.

6. The semiconductor device of claim 1, wherein the conductive filament includes oxygen vacancies.

7. The semiconductor device of claim 1, wherein the conductive filament extends from an interface between the third resistance change layer and the oxygen vacancy reservoir layer to reach an interface between the third resistance change layer and the second filament control layer.

8. The semiconductor device of claim 1,
wherein the conductive filament extends from an interface between the third resistance change layer and the oxygen vacancy reservoir layer to reach an interface between the second resistance change layer and the first filament control layer, and
wherein the conductive filament includes a first filament part disposed in the third resistance change layer and a second filament part disposed in the second resistance change layer.

9. The semiconductor device of claim 8, wherein the first filament part is disposed to overlap the second filament part with the second filament control layer interposed therebetween.

10. The semiconductor device of claim 1,
wherein the conductive filament extends from an interface between the third resistance change layer and the oxygen vacancy reservoir layer to reach an interface between the first resistance change layer and the first electrode layer, and
wherein the conductive filament includes a first filament part disposed in the third resistance change layer, a second filament part disposed in the second resistance change layer, and a third filament part disposed in the first resistance change layer.

11. The semiconductor device of claim 10,
wherein the first filament part is disposed to overlap the second filament part with the second filament control layer interposed therebetween, and
wherein the second filament part is disposed to overlap the first filament part with the first filament control layer interposed therebetween.

12. The semiconductor device of claim 1, wherein the oxygen vacancy reservoir layer includes at least one selected from the group consisting of tantalum (Ta), titanium (Ti), zirconium (Zr), vanadium (V), tungsten (W), ruthenium (Ru), tantalum oxide, titanium oxide, zirconium oxide, tungsten oxide, aluminum oxide, nickel oxide, copper oxide, manganese oxide, hafnium oxide, niobium oxide, and iron oxide.

13. A semiconductor device comprising:
a first electrode layer;
a first resistance change layer disposed on the first electrode layer;
a first metal layer disposed on the first resistance change layer and with a thickness of 0.5 nm to 3 nm;
a second resistance change layer disposed on the first metal layer;
a second metal layer disposed on the second resistance change layer and that is thinner than the first metal layer;
a third resistance change layer disposed on the second metal layer;
an oxygen vacancy reservoir layer disposed on the third resistance change layer; and
a second electrode layer disposed on the oxygen vacancy reservoir layer.

14. The semiconductor device of claim 13, further comprising a conductive filament that extends from an interface between the third resistance change layer and the oxygen vacancy reservoir layer to an interface selected from a first interface between the second metal layer and the third resistance change layer, a second interface between the first metal layer and the second resistance change layer, and a third interface between the first electrode layer and the first resistance change layer.

15. The semiconductor device of claim 14, wherein an electrical resistance is determined depending on the interface that the conductive filament reaches from among the first to third interfaces.

16. The semiconductor device of claim 13, wherein each of the first metal layer and the second metal layer includes one selected from the group consisting of platinum (Pt), gold (Au), palladium (Pd), molybdenum (Mo), nickel (Ni), tungsten (W), titanium (Ti), copper (Cu), aluminum (Al), ruthenium (Ru), and iridium (Ir).

17. The semiconductor device of claim 13,
wherein each of the first to third resistance change layers includes a resistance change material, and
wherein the resistance change material includes at least one of hafnium oxide, zirconium oxide, and hafnium zirconium oxide.

18. The semiconductor device of claim 13, wherein the oxygen vacancy reservoir layer includes at least one selected from the group consisting of tantalum (Ta), titanium (Ti), zirconium (Zr), vanadium (V), tungsten (W), ruthenium (Ru), tantalum oxide, titanium oxide, zirconium oxide, tungsten oxide, aluminum oxide, nickel oxide, copper oxide, manganese oxide, hafnium oxide, niobium oxide, and iron oxide.

19. A semiconductor device comprising:
a first electrode layer;
a first resistance change layer disposed on the first electrode layer;
a first filament control layer disposed on the first resistance change layer;
a second resistance change layer disposed on the first filament control layer;
a second filament control layer, disposed on the second resistance change layer, that is thinner than the first filament control layer;
a third resistance change layer disposed on the second filament control layer;
an oxygen vacancy reservoir layer disposed on the third resistance change layer; and
a second electrode layer disposed on the oxygen vacancy reservoir layer,
wherein a conductive filament corresponding to a resistance state of the semiconductor device is configured to be formed from an interface between the oxygen vacancy reservoir layer and the third resistance change layer to reach one of a first interface between the second filament control layer and the third resistance change layer, a second interface between the first filament control layer and the second resistance change layer, and a third interface between the first electrode layer and the first resistance change layer.

20. The semiconductor device of claim 19, wherein the first filament control layer has a thickness of 0.5 nm to 3 nm.
